(19) United States
(12) Patent Application Publication
(10) Pub. No.: US 2025/0204088 A1
(43) Pub. Date: Jun. 19, 2025

(54) JIG AND DISPLAY DEVICE MANUFACTURING METHOD USING THE JIG

(71) Applicant: Samsung Display Co., LTD., Yongin-si (KR)

(72) Inventors: SANGDUK LEE, Yongin-si (KR); HOIKWAN LEE, Yongin-si (KR); Jun Yeub LEE, Yongin-si (KR); BYOUNG JIN JIN, Yongin-si (KR); EUN-KYUNG YEON, Yongin-si (KR)

(21) Appl. No.: 18/775,644

(22) Filed: Jul. 17, 2024

(30) Foreign Application Priority Data
Dec. 19, 2023 (KR) 10-2023-0186271

(51) Int. Cl. H01L 33/00; H10K 59/12

(52) U.S. Cl. CPC H10H 20/01; H10K 59/1201; H10H 20/0362

(57) ABSTRACT

Provided is a jig including a stage including a resting groove in which a display module and a transparent film are rested, where a side of a notch portion defined in the display module is recessed in a plan view, and the transparent film is disposed on the display module, covers the display module, and comprises an upper surface coated with a transparent resin material. The jig includes a first stepped portion protruding from an inner surface of the stage defining the resting groove toward a center of the resting groove, and a second stepped portion protruding from the first stepped portion toward the center of the resting groove. An upper surface of the first stepped portion and an upper surface of the second stepped portion are parallel to a plane, and a shape of the second stepped portion corresponds to a shape of the notch portion.

This application claims priority to Korean Patent Application No. 10-2023-0186271, filed on Dec. 19, 2023, and all the benefits accruing therefrom under 35 U.S.C. § 119, the content of which in its entirety is herein incorporated by reference.

### BACKGROUND

### Field

The present disclosure herein relates to a jig and a display device manufacturing method using the jig, and more particularly, to a jig including a stepped portion and a display device manufacturing method using the jig.

### Description of the Related Art

A display device such as, for example, a television, a monitor, a smartphone, and a tablet PC, which provides an image to a user, includes a display panel for displaying the image. Various display panels such as, for example, liquid crystal display panels, organic light-emitting display panels, electrowetting display panels, and electrophoretic display panels have been developed. In some aspects, a display device may include a window for protecting an included display panel. The window may be attached to the display panel through a lamination process.

### SUMMARY

The present disclosure provides a jig that stably supports a transparent film due to inclusion of a stepped portion.

The present disclosure also provides a jig that prevents surface unevenness from being transferred to a coating window due to low surface roughness of a stepped portion.

The present disclosure provides a display device manufacturing method by which a coating window having low surface roughness is manufactured using a jig including a stepped portion.

An embodiment supported by the present disclosure provides a jig including a stage including a resting groove in which a display module and a transparent film are rested, wherein a side of a notch portion defined in the display module is recessed in a plan view, and the transparent film is disposed on the display module, covers the display module, and comprises an upper surface coated with a transparent resin material. The jig includes a first stepped portion protruding from an inner side surface of the stage defining the resting groove toward a center of the resting groove, and a second stepped portion protruding from the first stepped portion toward the center of the resting groove. An upper surface of the first stepped portion and an upper surface of the second stepped portion are parallel to a plane, and a shape of the second stepped portion corresponds to a shape of the notch portion.

In an embodiment, an average surface roughness of the upper surface of the second portion may be about 50 nm or less.

In an embodiment, the first stepped portion and the second stepped portion may include a metal material or glass.

In an embodiment, the first stepped portion and the second stepped portion may include a metal material, and the jig may further include a cover layer covering the upper surface of the second stepped portion.

In an embodiment, the first stepped portion and the second stepped portion may be in contact with a lower surface of the transparent film.

In an embodiment, an average surface roughness of the upper surface of the first stepped portion may be about 50 nm or less.

In an embodiment, the first stepped portion and the second stepped portion may not overlap the display module.

In an embodiment, the inner side surface of the stage may be in contact with an outer side of the transparent film.

In an embodiment, an outer side surface of the first stepped portion and an outer side surface of the second stepped portion may form one closed curve in a plan view, and a shape of the closed curve may correspond to a shape of the display module.

In an embodiment, a height from a lower surface of the stage defining the resting groove to the first stepped portion and a height from the lower surface of the stage defining the resting groove to the second stepped portion may each be equal to a height of the display module.

In an embodiment, a first light blocking pattern disposed along an outer side surface of the transparent film and a second light blocking pattern extending from the first light blocking pattern and overlapping the notch portion may be disposed on the transparent film, and the first stepped portion may overlap the first light blocking pattern.

In an embodiment, the second stepped portion may overlap the second light blocking pattern.

In an embodiment, the inner side surface of the stage may be release-coated.

In an embodiment supported by the present disclosure, a display device manufacturing method includes resting a display module and a transparent film on a jig, the jig including a first stepped portion, a second stepped portion, and a stage having a resting groove, wherein a side of a notch portion defined in the display module is recessed in a plan view, and the transparent film is disposed on the display module and covers the display module, applying a transparent resin material onto the transparent film, and forming a coating window disposed directly on the transparent film by curing a transparent resin material, wherein the coating window includes the transparent resin material, wherein a shape of the second stepped portion may correspond to a shape of the notch portion.

In an embodiment, in the resting of the display module and the transparent film on the jig, the transparent film may be in contact with an upper surface of the first stepped portion and an upper surface of the second stepped portion.

In an embodiment, the first stepped portion may protrude from an inner side surface of the stage defining the resting groove toward a center of the resting groove, the second stepped portion may protrude from the first stepped portion toward the center of the resting groove, and an upper surface of the first stepped portion and an upper surface of the second stepped portion may be parallel to a plane.

In an embodiment, the display device manufacturing method may further include forming a light blocking pattern on the transparent film after resting the transparent film on the jig, wherein the light blocking pattern may include a first light blocking pattern disposed along an outer side surface of the transparent film and a second light blocking pattern extending from the first light blocking pattern and corresponding to the notch portion.

In an embodiment, the display device manufacturing method may include release-coating an inner side surface of the stage.

In an embodiment, a maximum height difference between a highest portion of an upper surface of the coating window and a lowest portion of the upper surface may be about 0.95 μm or less.

In an embodiment, an average surface roughness of an upper surface of the second stepped portion may be about 50 nm or less.

### BRIEF DESCRIPTION OF THE FIGURES

The accompanying drawings are included to provide a further understanding of embodiments supported by the present disclosure, and are incorporated in and constitute a part of this specification. The drawings illustrate embodiments supported by the present disclosure and, together with the description, serve to explain principles of supported by aspects of the present disclosure. In the drawings:

FIG. 1 is a perspective view of a display device according to an embodiment supported by the present disclosure;

FIG. 2A is an exploded perspective view of a display device according to an embodiment supported by the present disclosure;

FIG. 2B is an exploded perspective view of a display device according to an embodiment supported by the present disclosure;

FIG. 3 is a cross-sectional view taken along line I-I′ in FIG. 2A according to an embodiment supported by the present disclosure;

FIG. 4 is a cross-sectional view taken along line II-II′ in FIG. 2A according to an embodiment supported by the present disclosure;

FIG. 5A is a plan view of a transparent film according to an embodiment supported by the present disclosure;

FIG. 5B is a plan view of a display module according to an embodiment supported by the present disclosure;

FIG. 6 is a perspective view of a jig, a transparent film, and a display module according to an embodiment supported by the present disclosure;

FIG. 7 is a plan view of a jig according to an embodiment supported by the present disclosure;

FIG. 8 is a plan view illustrating that a display module and a transparent film are rested on a jig according to an embodiment supported by the present disclosure;

FIG. 9 is a cross-sectional view taken along line III-III′ in FIG. 8 according to an embodiment supported by the present disclosure;

FIG. 10 is a cross-sectional view taken along line IV-IV′ in FIG. 8 according to an embodiment supported by the present disclosure;

FIG. 11 is a cross-sectional view illustrating that a resin material is applied on a transparent film in FIG. 10 according to an embodiment supported by the present disclosure;

FIG. 12 is a cross-sectional view illustrating that the applied resin material in FIG. 11 according to an embodiment supported by the present disclosure is being cured;

FIG. 13 is a cross-sectional view illustrating a lower module, a display module, a transparent film, and a coating window according to an embodiment supported by the present disclosure;

FIG. 14 is a graph illustrating a height difference of an upper surface of a coating window according to an embodiment supported by the present disclosure;

FIG. 15 is a cross-sectional view illustrating that a resin material is applied on the transparent film in FIG. 10 according to an embodiment supported by the present disclosure; and

FIG. 16 is a flowchart illustrating operations of a display device manufacturing method according to an embodiment supported by the present disclosure.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween.

Like reference numerals or symbols refer to like elements throughout. In some aspects, in the drawings, the thicknesses, the ratios, and the dimensions of elements are exaggerated for effective description of technical contents. The term “and/or” includes all of one or more combinations which the associated elements may define.

Although the terms first, second, and the like may be used to describe various elements, these elements should not be limited by these terms. These terms are used to distinguish one element from another element. For example, a first element may be referred to as a second element, and similarly, a second element may also be referred to as a first element without departing from the scope of the present disclosure. The singular forms include the plural forms as well unless the context clearly indicates otherwise.

In some aspects, terms such as, for example, “below”, “lower”, “above”, “upper” are used to describe the relationships of the elements illustrated in the drawings. These terms have relative concepts and are described on the basis of the directions indicated in the drawings.

It will be understood that the terms such as, for example, “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which the present disclosure belongs. In some aspects, terms, such as those defined in commonly used dictionaries, should be interpreted as having a meaning that is consistent with their meaning in the context of the relevant art and should not be interpreted in an overly idealized or overly formal sense unless expressly so defined herein.

Hereinafter, embodiments supported by the present disclosure will be described with reference to the accompanying drawings.

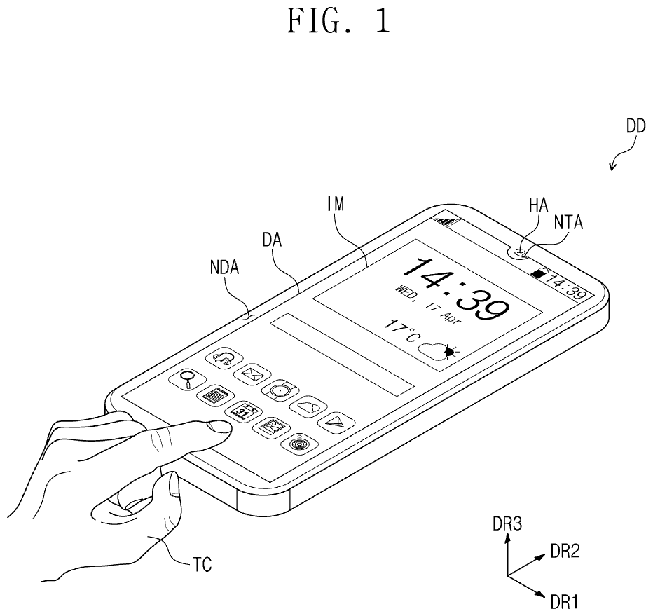

FIG. 1 is a perspective view of a display device according to an embodiment supported by the present disclosure.

Referring to FIG. 1, a portable terminal is illustrated as an example of a display device DD according to an embodiment supported by the present disclosure. The portable terminal may include a tablet PC, a smartphone, a personal digital assistant (PDA), a portable multimedia player (PMP), a game console, a wristwatch-type electronic device, or the like. However, embodiments supported by the present disclosure are not limited thereto.

The display device DD according to embodiments supported by the present disclosure may be used in a large-sized electronic apparatus such as, for example, a television or an outdoor billboard as well as a small- or medium-sized electronic apparatus such as, for example, a personal computer, a laptop, a car navigation unit, and a camera. These are simply presented as examples, and the display device DD may thus also be employed in other electronic apparatuses without departing from the spirit of aspects of the present disclosure.

As illustrated in FIG. 1, a display surface on which an image IM is displayed is parallel to a plane defined by a first direction DR1 and a second direction DR2. The display device DD includes a plurality of regions which are distinguished from each other on the display surface. The display surface includes a display region DA in which the image IM is displayed, and a non-display region NDA adjacent to the display region DA. The non-display region NDA may be referred to as a bezel region. As an example, the display region DA may have a quadrangular shape. The non-display region NDA surrounds the display region DA. In some aspects, although not illustrated, the display device DD may include a partially curved portion as an example. As a result, a portion of the display region DA may have a curved shape.

The non-display region NDA may include a hole region HA and a notch region NTA. The hole region HA may be a region in which an external signal is sensed. The hole region HA may overlap an electronic module CAM which senses the external signal. The electronic module CAM may be any module which senses the external signal. For example, the hole region HA may overlap a camera module and sense an external image. The hole region HA may overlap a proximity illuminance sensor and sense an external object and brightness. FIG. 1 illustrates a single hole region HA having a circular shape, but embodiments of the present disclosure are not limited thereto. For example, the hole region HA may be provided in plurality, and a plurality of hole regions HA may have different shapes from each other.

The hole region HA may be spaced apart from the display region DA. The hole region HA may be spaced apart from the display region DA with the non-display region NDA between the hole region HA and the display region DA. A transmittance of the hole region HA may be higher than a transmittance of the display region DA.

The notch region NTA may overlap the hole region HA and surround the hole region HA. The notch region NTA may have a shape such that a side of the display region DA is recessed toward a central portion of the display region DA in a plan view. The notch region NTA may have a shape such that a side of the non-display region NDA protrudes toward the central portion of the display region DA in a plan view. The notch region NTA may be disposed such that the notch region NTA is adjacent to an outermost line of the display region DA in a plan view.

A front surface (or an upper surface) and a rear surface (or a lower surface) of each member constituting the display device DD may be opposed to each other in a third direction DR3, and a normal direction of each of a front surface and a rear surface may be substantially parallel to the third direction DR3. A distance between a rear surface and a front surface defined along the third direction DR3 may correspond to a thickness of a member (or a unit). As used herein, the wording “in a plan view” may be defined as being viewed in the third direction DR3. As used herein, the wording “in a cross-sectional view” may be defined as being viewed in the first direction DR1 or in the second direction DR2. Directions indicated by the first to third directions DR1, DR2, and DR3 may have relative concepts and may thus be changed into other directions. As used herein, “overlap” may mean overlapping in a plan view unless otherwise defined.

A front surface (or an upper surface, or a first surface) and a rear surface (or a lower surface, or a second surface) of each member are defined with respect to a direction in which the image IM is displayed. However, directions indicated by the first to third directions DR1, DR2, and DR3 may be relative and may thus be changed into other directions. Hereinafter, first to third directions are directions respectively indicated by the first to third directions DR1, DR2, and DR3 and denoted as the same reference numerals or symbols.

The display device DD according to an embodiment supported by the present disclosure may sense a user's touch input TC applied from the outside. The user's touch input TC may include external inputs in various forms such as, for example, a part of a user's body, light, heat, or pressure. In an embodiment, it may be assumed and described that the user's input is a user's hand applied to a front surface, but this is an example, and as described herein, the user's touch input TC may be provided in various forms. In some aspects, the display device DD may sense a user's input applied to a side surface or a rear surface of the display device DD according to a structure of the display device DD, and the display device DD is not limited to any one embodiment.

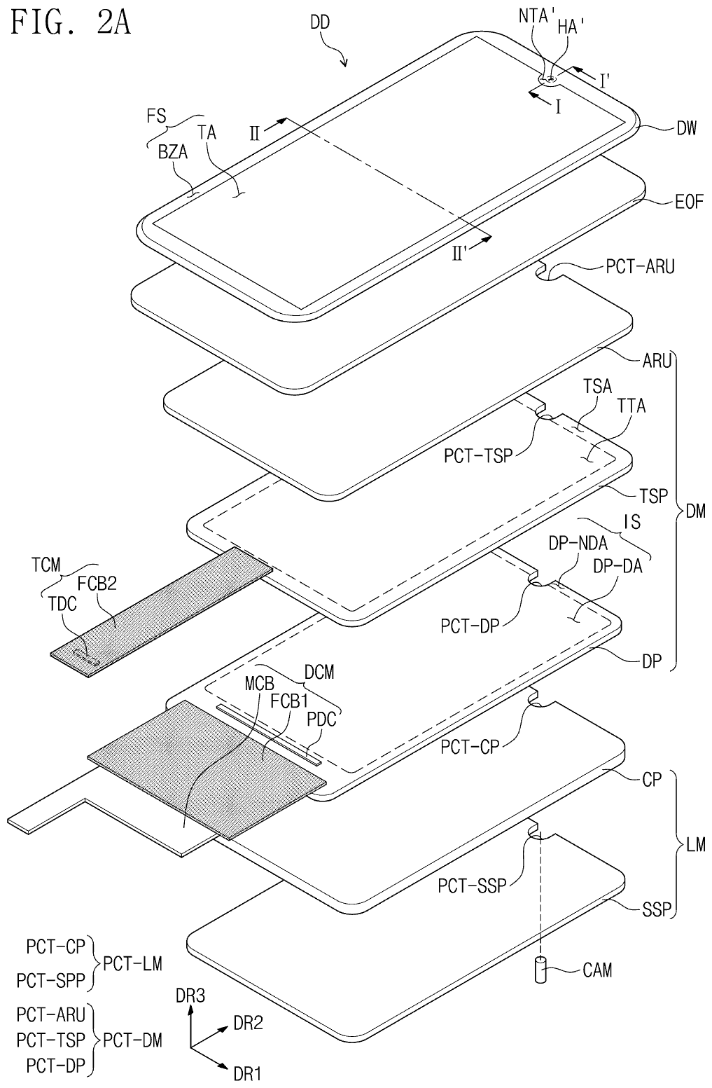

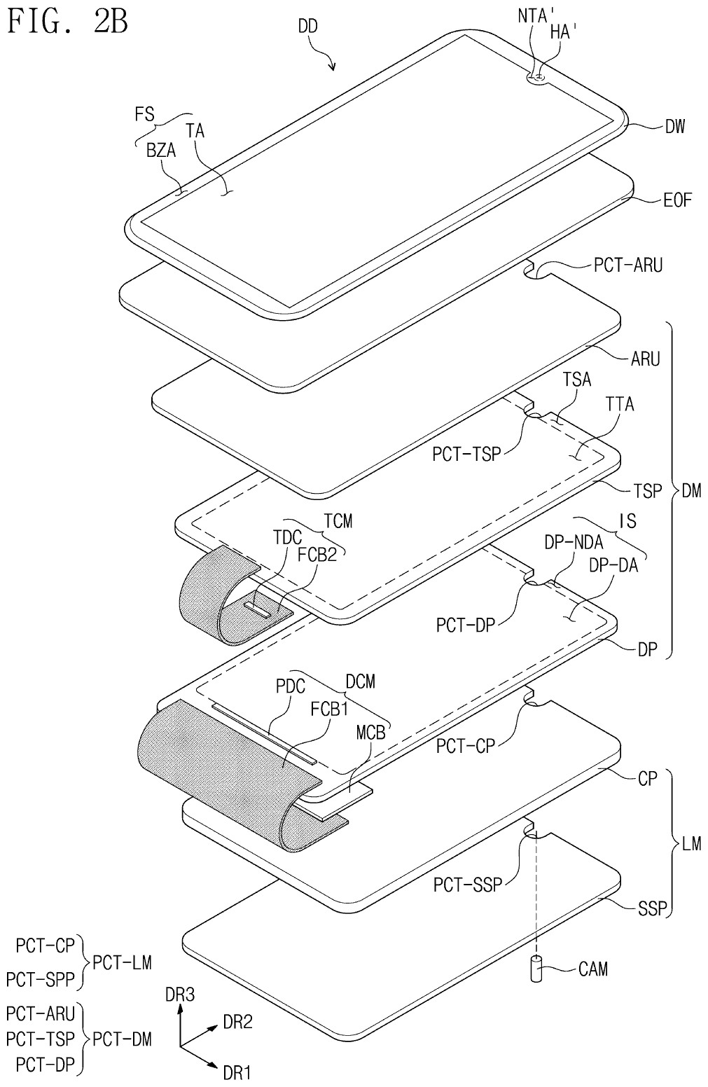

FIGS. 2A and 2B are exploded perspective views of a display device according to an embodiment supported by the present disclosure. More specifically, FIG. 2A is an exploded perspective view of a display device DD in which a first circuit board FCB1 and a second circuit board FCB2 are not bent, and FIG. 2B is an exploded perspective view of the display device DD in which the first circuit board FCB1 and the second circuit board FCB2 are bent.

Referring to FIGS. 2A and 2B, the display device DD may include a coating window DW, a transparent film EOF, a display module DM, and a lower module LM. The coating window DW may be disposed directly on the transparent film EOF. Here, being disposed directly may mean being disposed without an adhesive or adhesive layer additionally between an element (e.g., coating window DW) and another element (e.g., transparent film EOF).

The coating window DW may provide a front surface FS of the display device DD. A front surface FS of the coating window DW may include a transmission region TA and a bezel region BZA. The transmission region TA of the coating window DW may be an optically transparent region. The coating window DW may transmit the image IM provided by a display panel DP through the transmission region TA, and a user may view the image IM (see FIG. 1).

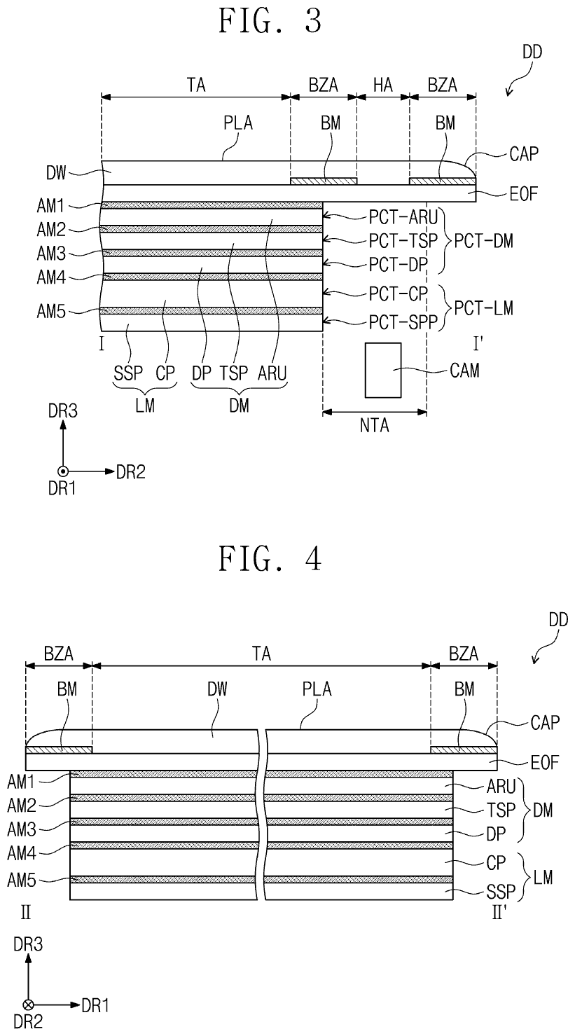

The bezel region BZA of the coating window DW may overlap a light blocking pattern BM (see FIG. 4) to be described later. The light blocking pattern BM may include a material of a predetermined color. The bezel region BZA of the coating window DW may prevent a component of the display panel DP disposed to overlap a light blocking pattern BM (see FIG. 3) from being viewed from the outside.

The bezel region BZA may be adjacent to the transmission region TA. A shape of the transmission region TA may be substantially defined by the bezel region BZA. For example, the bezel region BZA may be disposed on an outer side of the transmission region TA and surround the transmission region TA. However, this is illustrated as an example, and the bezel region BZA may be adjacent to a single side of the transmission region TA or omitted. In some aspects, the bezel region BZA may also be disposed on a side surface, not on the front surface, of the display device DD. The bezel region BZA may correspond to the non-display region NDA (see FIG. 1) in FIG. 1.

The bezel region BZA may include a notch region NTA′. The notch region NTA′ may surround a hole region HA′. The notch region NTA′ may have a shape such that a side of the transmission region TA is recessed toward a central portion of the transmission region TA in a plan view. The notch region NTA′ may have a shape such that a side of the bezel region BZA protrudes toward a central portion of a display region DA in a plan view. The notch region NTA′ may be disposed such that the notch region NTA′ is adjacent to a boundary between the bezel region BZA and the transmission region TA. The notch region NTA′ may overlap the hole region HA′. The notch region NTA′ may surround the hole region HA′. The notch region NTA′ may correspond to the notch region NTA (see FIG. 1) in FIG. 1, and the hole region HA′ may correspond to the hole region HA (see FIG. 1) in FIG. 1.

The coating window DW may include an optically transparent insulating material. The coating window DW may include a curable resin material. The coating window DW may have a single- or multi-layered structure. The coating window DW may be formed by applying a transparent resin material onto the transparent film EOF and curing the applied transparent resin material. Since, according to embodiments supported by the present disclosure, a lamination process of attaching a window formed of glass to a panel is skipped, the display device DD including the coating window DW may be manufactured through a simplified manufacturing process and with reduced cost.

The coating window DW may include a functional coating layer such as, for example, an anti-fingerprint layer, an anti-reflective layer, and a hard coating layer. In this embodiment, the coating window DW having a flat shape in a display region DP-DA is illustrated, but the shape of the coating window DW is not limited thereto and may be changed. Edges of the coating window DW facing each other in a first direction DR1 may provide a curved surface.

The transparent film EOF may be disposed between the coating window DW and the display module DM. The transparent film EOF may be disposed directly on a lower surface of the coating window DW. The transparent film EOF may be an optically transparent film. The transparent film EOF may include a colorless transparent material having an excellent optical property. For example, the transparent film EOF may be a film including polyimide (PI), polyethylene terephthalate (PET), or the like. However, a material of the transparent film EOF is not limited thereto, and the transparent film EOF may include other various materials supportive of features of the transparent film EOF.

The transparent film EOF may be disposed on an optical unit ARU. The transparent film EOF may have a shape of a flat plate extending in a direction parallel to a plane defined by the first direction DR1 and a second direction DR2. The transparent film EOF may cover the display module DM in a plan view. The transparent film EOF may cover a display region DP-DA and a non-display region DP-NDA in a plan view. The transparent film EOF may cover the transmission region TA and the bezel region BZA in a plan view. The transparent film EOF may cover a touch region TTA and a touch peripheral region TSA in a plan view. A planar area size of the transparent film EOF may be equal to or greater than a planar area size of the coating window DW.

The transparent film EOF may serve as a base on which a resin material for forming the coating window DW may be applied. That is, for example, the transparent film EOF having a shape of a flat plate may be disposed below the coating window DW, and the resin material in a liquid state may be applied on the transparent film EOF. In some aspects, the transparent film EOF may cover the bent flexible boards FCB1 and FCB2 in a plan view, which may prevent the resin material from flowing into the flexible boards FCB1 and FCB2 and being cured when the resin material is applied onto the transparent film EOF. If the resin material flows into the flexible boards FCB1 and FCB2 and is cured, a crack may occur when the flexible boards FCB1 and FCB2 are bent in a bending process. The transparent film EOF may prevent such a risk of a crack.

A thickness of the transparent film EOF may be about 20 μm to about 200 μm. If the thickness of the transparent film EOF is less than about 20 μm, the transparent film EOF may be deformed when the resin material is applied on the transparent film EOF. If the thickness of the transparent film EOF is more than about 200 μm, the display device DD may become excessively thick.

The display module DM may be disposed on a rear surface of the coating window DW and generate the image IM (see FIG. 1). In some aspects, the display module DM may sense the user's touch input TC (see FIG. 1).

In this embodiment, the display module DM which provides a flat display surface is illustrated as an example, but the shape of the display module DM is not limited thereto and may be changed. Edges of the display module DM facing each other in the first direction DR1 may also be bent from central portions and provide a curved surface.

The display module DM may include the optical unit ARU, a touch sensing panel TSP, the display panel DP, and a driving control module DCM. An upper notch portion PCT-DM (or a notch portion) may be defined in the display module DM. The upper notch portion PCT-DM may include a first notch portion PCT-ARU, a second notch portion PCT-TSP, and a third notch portion PCT-DP. A shape of the upper notch portion PCT-DM may correspond to the shape of the notch region NTA′.

The optical unit ARU may be disposed on the display panel DP and overlap a display region DP-DA. The optical unit ARU may be disposed between the display panel DP and the transparent film EOF. The optical unit ARU may reduce a reflectance for light incident from the outside. The optical unit ARU may include at least one of a retarder, a polarizer, a polarizing film, or a polarizing filter. The optical unit ARU may be attached to the display panel DP through an adhesive layer. However, a type of the optical unit ARU is an example, and is not limited thereto. For example, the optical unit ARU may include a color filter.

The first notch portion PCT-ARU, a side of which is recessed in a plan view, may be defined in the optical unit ARU. A shape of the first notch portion PCT-ARU may correspond to the shape of the notch region NTA′. The first notch portion PCT-ARU may be recessed from a side of the optical unit ARU in a direction opposite to the second direction DR2.

The display panel DP may be disposed between the coating window DW and a supporting panel SSP. The display panel DP may be disposed between the touch sensing panel TSP and a protective panel CP. The display panel DP may display an image in response to an electrical signal. The display panel DP according to an embodiment may be an emissive display panel, but an embodiment supported by the present disclosure is not particularly limited thereto. For example, the display panel DP may be an organic light-emitting display panel, an inorganic light-emitting display panel, an organic-inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the organic-inorganic light-emitting display panel may include an organic-inorganic light-emitting material. A light-emitting layer of the quantum dot light-emitting display panel may include a quantum dot, a quantum rod, or the like.

The image IM (see FIG. 1) provided by the display device DD may be displayed on a front surface IS of the display panel DP. The front surface IS of the display panel DP may include a display region DP-DA and a non-display region DP-NDA. Here, the display region DP-DA may correspond to the display region DA (see FIG. 1) in FIG. 1, and the non-display region DP-NDA may correspond to the non-display region NDA (see FIG. 1) in FIG. 1.

The display region DP-DA may be a region which is activated in response to an electrical signal and in which an image is displayed. According to an embodiment, the display region DP-DA of the display panel DP may correspond to the transmission region TA of the coating window DW. As used herein, the wording “a region/a portion corresponds to a region/a portion” means that “regions/portions overlap each other”, and the wording is not limited to a case in which the regions/the portions have the same area size and/or the same shape. For example, the wording may include cases in which the regions/the portions are different with respect to area size and/or shape.

The non-display region DP-NDA may be adjacent to an outer side of the display region DP-DA. For example, the non-display region DP-NDA may surround the display region DP-DA. However, embodiments of the present disclosure are not limited thereto, and the non-display region DP-NDA may be defined in various shapes.

The non-display region DP-NDA may be a region in which a driving line or a driving circuit for driving elements disposed in the display region DP-DA, various types of signal lines for providing an electrical signal, pads, and other components are disposed. The non-display region DP-NDA of the display panel DP may correspond to the bezel region BZA of the coating window DW. The bezel region BZA may prevent components of the display panel DP disposed in the non-display region DP-NDA from being viewed from the outside.

The third notch portion PCT-DP, a side of which is recessed in a plan view, may be defined in the display panel DP. A shape of the third notch portion PCT-DP may correspond to the shape of the notch region NTA′. The third notch portion PCT-DP may be recessed from a side of the display panel DP in a direction opposite to the second direction DR2. A shape of the third notch portion PCT-DP may correspond to those of the first notch portion PCT-ARU and the second notch portion PCT-TSP.

The driving control module DCM includes a main circuit board MCB (or a driving circuit board), the first circuit board FCB1, and a panel driving circuit PDC. The first circuit board FCB1 may be connected to an end portion of the display panel DP and electrically connect the main circuit board MCB and the display panel DP.

The panel driving circuit PDC may be disposed in the non-display region DP-NDA of the display panel DP. The panel driving circuit PDC may be realized as an integrated circuit. Although not separately illustrated, the display device DD may include a plurality of passive elements and active elements mounted on the main circuit board MCB. The main circuit board MCB may be a rigid circuit board or a flexible circuit board, and the first circuit board FCB1 may be a flexible circuit board. The main circuit board MCB may be located on a rear surface of the display panel DP.

The first circuit board FCB1 may be disposed in the non-display region DP-NDA of the display panel DP and bent. The first circuit board FCB1 may be connected to the end portion of the display panel DP and electrically connect the main circuit board MCB and the display panel DP. The first circuit board FCB1 may be bent such that one end of the first circuit board FCB1 is disposed on the front surface of the display panel DP and another end of the first circuit board FCB1 is disposed on the rear surface of the display panel DP. The first circuit board FCB1 may be bent such that an end of the first circuit board FCB1 is located on the rear surface of the display panel DP. An end of the first circuit board FCB1 and a rear surface of the non-display region NDA may be opposed to each other in a third direction DR3. The main circuit board MCB may be located on the rear surface of the display panel DP.

The touch sensing panel TSP may be disposed between the display panel DP and the optical unit ARU and connected to the second circuit board FCB2. The touch sensing panel TSP may acquire coordinate information about the user's input TC (see FIG. 1). The touch sensing panel TSP may sense inputs in various forms which are provided from outside the display device DD. In an embodiment, the touch sensing panel TSP may sense an input from a user's body, but embodiments of the present disclosure are not limited thereto. For example, the touch sensing panel TSP may sense external inputs in various forms such as, for example, light, heat, or pressure. In some aspects, the touch sensing panel TSP may be capable of sensing an input which contacts a sensing surface and an input which is close to but does not contact the sensing surface.

The touch sensing panel TSP may be, for example, a capacitive-type touch panel, an electromagnetic induction-type touch panel, or the like. Such a touch sensing panel TSP may include a base layer, sensing electrodes, and signal lines connected to the sensing electrodes.

The second notch portion PCT-TSP, a side of which is recessed in a plan view, may be defined in the touch sensing panel TSP. A shape of the second notch portion PCT-TSP may correspond to the shape of the notch region NTA′. The second notch portion PCT-TSP may have a shape corresponding to those of the first notch portion PCT-ARU and the third notch portion PCT-DP. The second notch portion PCT-TSP may be recessed from a side of the touch sensing panel TSP in a direction opposite to the second direction DR2.

A touch control unit TCM may include the second circuit board FCB2 and a touch driving circuit TDC. The second circuit board FCB2 may electrically connect the main circuit board MCB and the touch sensing panel TSP, and the touch driving circuit TDC may be mounted on the second circuit board FCB2. The second circuit board FCB2 may be bent like the first circuit board FCB1. The second circuit board FCB2 may electrically connect the main circuit board MCB and the touch sensing panel TSP. The touch driving circuit TDC may be realized as an integrated circuit. The second circuit board FCB2 may be a flexible circuit board.

The lower module LM may include the protective panel CP and the supporting panel SSP. A lower notch portion PCT-LM may be defined in the lower module LM. The lower notch portion PCT-LM may include a fourth notch portion PCT-CP and a fifth notch portion PCT-SPP.

The protective panel CP may be disposed on the rear surface of the display panel DP to protect the display panel DP from an impact. The protective panel CP may include a plastic film as a base layer. The protective panel CP may have a single- or multi-layered structure.

The fourth notch portion PCT-CP, a side of which is recessed in a plan view, may be defined in the protective panel CP. A shape of the fourth notch portion PCT-CP may correspond to the shape of the notch region NTA′. The fourth notch portion PCT-CP may be recessed from a side of the protective panel CP in a direction opposite to the second direction DR2.

The supporting panel SSP may be disposed on a rear surface of the protective panel CP and support the display panel DP and the protective panel CP. The supporting panel SSP may be a metal plate having at least a reference rigidity. The supporting panel SSP may be a stainless-steel plate. The supporting panel SSP may have a black color to block external light incident onto the display panel DP.

The fifth notch portion PCT-SPP, a side of which is recessed in a plan view, may be defined in the supporting panel SSP. A shape of the fifth notch portion PCT-SPP may correspond to the shape of the notch region NTA′. A shape of the fifth notch portion PCT-SPP may correspond to the shape of the fourth notch portion PCT-CP. The fifth notch portion PCT-SPP may be recessed from a side of the supporting panel SSP in a direction opposite to the second direction DR2.

FIG. 3 is a cross-sectional view taken along line I-I′ in FIG. 2A according to an embodiment supported by the present disclosure.

FIG. 3 illustrates the display panel DP as a single layer, but the display panel DP is not limited thereto. In some embodiments, the display panel DP may have a multi-layered structure. The display panel DP may include a base layer, a circuit layer, a light-emitting element layer, and an encapsulation layer. A person skilled in the art could understand that other general-purpose components may further be included in the display panel DP in addition to the above components.

FIG. 3 illustrates a stacked structure of the display device DD. The display device DD may include the lower module LM, the display module DM, the transparent film EOF disposed on the display module DM, and the coating window DW disposed directly on the transparent film EOF.

Each of a first adhesive layer AM1 to a fifth adhesive layer AM5 to be described herein may be a pressure sensitive adhesive (PSA) film, an optically clear adhesive (OCA) film, or an optically clear resin (OCR). The first adhesive layer AM1 to the fifth adhesive layer AM5 include a photocurable adhesive material or a thermosetting adhesive material, and a material of the first adhesive layer AM1 to the fifth adhesive layer AM5 is not particularly limited. One or more of the first adhesive layer AM1 to the fifth adhesive layer AM5 may be omitted.

The display module DM may include the display panel DP, the touch sensing panel TSP, the optical unit ARU, and the first to third adhesive layers AM1 to AM3. The upper notch portion PCT-DM defined in the display module DM may be aligned in a cross-sectional view. That is, for example, the first notch portion PCT-ARU, the second notch portion PCT-TSP, and the third notch portion PCT-DP may be aligned in a cross-sectional view.

The display panel DP may be disposed between the touch sensing panel TSP and the protective panel CP. The display panel DP may display an image in response to an electrical signal. An upper surface of the display panel DP may be bonded to a lower surface of the touch sensing panel TSP through the third adhesive layer AM3. A lower surface of the display panel DP may be bonded to an upper surface of the protective panel CP through the fourth adhesive layer AM4. In some embodiments, the third adhesive layer AM3 and the fourth adhesive layer AM4 may be omitted. For example, the touch sensing panel TSP may be disposed directly on the upper surface of the display panel DP.

The touch sensing panel TSP may be disposed on the display panel DP and sense an input signal. The touch sensing panel TSP may be disposed between the display panel DP and the optical unit ARU.

The optical unit ARU may be disposed on the display panel DP. The optical unit ARU may be disposed between the touch sensing panel TSP and the transparent film EOF. The optical unit ARU may be attached onto the touch sensing panel TSP through the second adhesive layer AM2. However, in some embodiments, the second adhesive layer AM2 may be omitted.

The transparent film EOF may be disposed on the display module DM. The transparent film EOF may be disposed on the optical unit ARU. The transparent film EOF may extend over and overlap all of the transmission region TA, the bezel region BZA, a hole region HA, and a notch region NTA. The transparent film EOF may cover the display module DM disposed below the transparent film EOF in a plan view.

An outer side surface of the transparent film EOF may protrude in a direction away from the transmission region TA in a plan view further than an outer side surface of each of the lower module LM and the display module DM.

A light blocking pattern BM may be disposed directly on the transparent film EOF. The light blocking pattern BM may include a light blocking material, which may prevent a component disposed below the light blocking pattern BM from being viewed from the outside. The light blocking material may be a resin having a black color and through which light is not transmitted. The light blocking pattern BM may be disposed to such that the light blocking pattern BM overlaps the non-display region DP-NDA (see FIG. 2B) of the display panel DP. The light blocking pattern BM may be disposed such that the light blocking pattern BM overlaps the bezel region BZA of the coating window DW. The light blocking pattern BM may overlap the upper notch portion PCT-DM and the lower notch portion PCT-LM in a plan view.

The first adhesive layer AM1 may be disposed between the transparent film EOF and the optical unit ARU and bond the transparent film EOF to the optical unit ARU.

If the coating window DW is formed by applying and then curing a resin material such as, for example, a transparent resin, additionally coupling the light blocking pattern BM to the coating window DW may be prevented. Therefore, in some embodiments, the optically transparent film EOF may be formed separately from the coating window DW and the light blocking pattern BM may be printed on the transparent film EOF, such that the light blocking pattern BM may cover the bezel region BZA.

The coating window DW may be disposed directly on the transparent film EOF. The coating window DW may be formed by applying and curing a transparent resin material such as, for example, a resin. An upper surface of the coating window DW may include a first surface PLA which is flat and a second surface CAP which is curved toward the transparent film EOF in a direction away from the transmission region TA. The curved second surface CAP may be formed since the application of the resin material up to an outer peripheral portion of the transparent film EOF may not be uniform due to viscosity of the resin material when the resin material is applied. However, the second surface CAP may not be formed according to a type of the resin material, and may also be removed through an additional cutting process.

An electronic module CAM may overlap the hole region HA. The electronic module CAM may overlap the notch region NTA. The electronic module CAM may receive an external signal passing through the hole region HA.

The lower module LM may include the protective panel CP and the supporting panel SSP. The lower notch portion PCT-LM may be aligned in a cross-sectional view. That is, for example, the fourth notch portion PCT-CP and the fifth notch portion PCT-SPP of the lower module LM may be aligned in a cross-sectional view. The lower notch portion PCT-LM may be aligned with the upper notch portion PCT-DM in a cross-sectional view. That is, for example, the first notch portion PCT-ARU, the second notch portion PCT-TSP, the third notch portion PCT-DP, the fourth notch portion PCT-CP, and the fifth notch portion PCT-SPP may be aligned in a cross-sectional view. The outer side surface of the lower module LM may be more adjacent to the transmission region TA than the outer side surface of the transparent film EOF.

The protective panel CP may be disposed on the lower surface of the display panel DP. The protective panel CP may protect the display panel DP from an impact transferred from below. The protective panel CP may have a multi-layered structure. For example, the protective panel CP may include a barrier layer having a color that has a low light transmittance, and the protective panel CP may include a cushion layer disposed on a lower surface of the barrier layer and formed of a material having high elasticity to absorb an impact transferred from below the display panel DP. The barrier layer and the cushion layer may be bonded to each other through an adhesive layer.

The supporting panel SSP may be disposed below the protective panel CP and support the display panel DP and the protective panel CP. The supporting panel SSP may be a metal plate having at least a predetermined reference rigidity. For example, the supporting panel SSP may be a stainless-steel plate. The supporting panel SSP may have a black color to block external light incident onto the display panel DP.

FIG. 4 is a cross-sectional view taken along line II-II′ in FIG. 2A according to an embodiment supported by the present disclosure.

Referring to FIG. 4, the display device DD may have a structure in which the lower module LM, the display module DM, the transparent film EOF, and the coating window DW are sequentially stacked. The display device DD may have a structure in which the supporting panel SSP, the protective panel CP, the display panel DP, the touch sensing panel TSP, the optical unit ARU, the transparent film EOF, and the coating window DW are sequentially stacked.

The bezel region BZA may be disposed such that the bezel region BZA is adjacent to two sides of the transmission region TA. The bezel region BZA may correspond to a light blocking pattern BM. An outer side surface of each of the light blocking pattern BM and the transparent film EOF in a cross-sectional view may protrude toward the outside further than an outer side surface of each of the display module DM and the lower module LM. That is, for example, the outer side surface of each of the light blocking pattern BM and the transparent film EOF in a cross-sectional view may protrude further than the outer side surface of each of the display module DM and the lower module DM along a first direction DR1 which is a direction away from the transmission region TA corresponding to the display region DP-DA (see FIG. 2B) or a direction opposite to the first direction DR1. The transparent film EOF may cover the display module DM and the lower module LM in a plan view. A portion of the light blocking pattern BM may overlap the display module DM in a plan view.

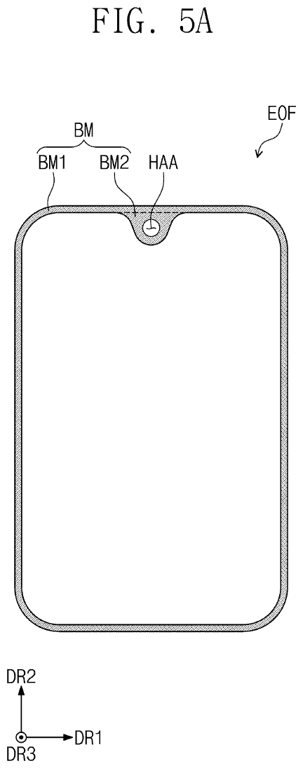

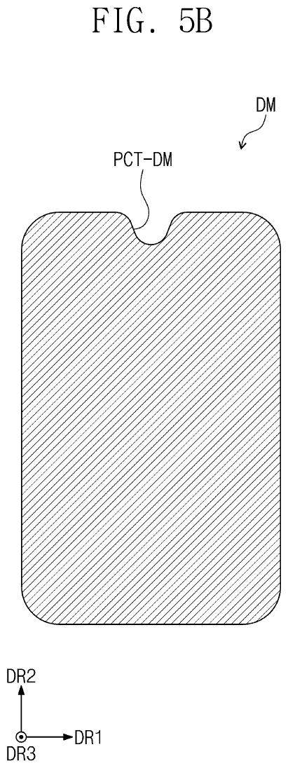

FIG. 5A is a plan view of a transparent film according to an embodiment supported by the present disclosure.

Referring to FIG. 5A, a light blocking pattern BM may be disposed on a transparent film EOF. The light blocking pattern BM may be disposed along an outer peripheral surface of the transparent film EOF. The light blocking pattern BM may include a first light blocking pattern BM1 and a second light blocking pattern BM2.

The first light blocking pattern BM1 may be disposed along an outer side surface of the transparent film EOF. The first light blocking pattern BM1 may be disposed with a constant thickness along the outer side surface of the transparent film EOF. The second light blocking pattern BM2 may extend from the first light blocking pattern BM1 and correspond to an upper notch portion PCT-DM and a lower notch portion PCT-LM. The second light blocking pattern BM2 may extend from a side of the first light blocking pattern BM1 toward a central portion of the transparent film EOF. A hole corresponding to a hole region HAA may be formed in the second light blocking pattern BM2. The hole region HAA may correspond to the hole region HA′ (see FIG. 2A) in FIG. 2A. The second light blocking pattern BM2 may surround the hole region HAA.

FIG. 5B is a plan view of a display module according to an embodiment supported by the present disclosure.

Referring to FIG. 5B, an upper notch portion PCT-DM recessed toward a center of a display module DM in a plan view may be defined in an outer side surface of the display module DM. A shape of the upper notch portion PCT-DM may correspond to the shape of the notch region NTA′ (see FIG. 2A).

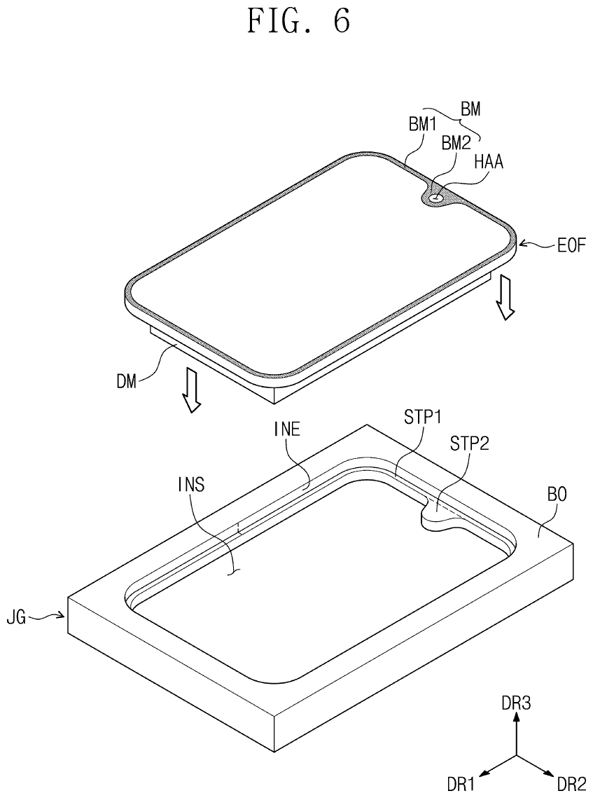

FIG. 6 is a perspective view of a jig, a transparent film, and a display module according to an embodiment supported by the present disclosure. Hereinafter, the same components as the components described with reference to FIGS. 1 to 5 will be denoted using the same reference numerals or symbols, and repeated descriptions thereof will be omitted.

Referring to FIG. 6, a stacked structure (hereinafter, an upper module) in which a display module DM and a transparent film EOF are coupled to each other may be rested on a jig JG having a resting groove INS defined therein. A shape of the resting groove INS may correspond to the shapes of the upper module DM and EOF. A lower surface of the jig JG defining the resting groove INS may support a lower surface of the display module DM. The jig JG may include a stage BO, a first stepped portion STP1, and a second stepped portion STP2. The jig JG may include a metal material or glass. For example, the jig JG may include pre-hardened steel.

The stage BO may serve as a body of the jig JG. A planar area size of the stage BO may be greater than a planar area size of the transparent film EOF. The first stepped portion STP1 and the second stepped portion STP2 may be defined in an inner side surface INE of the stage BO defining the resting groove INS such that the upper module is further stably rested on the stage BO. The inner side surface INE of the stage BO may extend from an outer periphery of the first stepped portion STP1 along a third direction DR3.

The first stepped portion STP1 may protrude from the inner side surface INE of the stage BO defining the resting groove INS toward a center of the resting groove INS. The first stepped portion STP1 may be formed to a constant thickness along the inner side surface INE of the stage BO defining the resting groove INS. A height from a lower surface of the stage BO defining the resting groove INS to an upper surface of the first stepped portion STP1 may be equal to a height of the display module DM. The first stepped portion STP1 may support an outer peripheral surface of the transparent film EOF when the upper module is rested in the resting groove INS.

The second stepped portion STP2 may protrude from the first stepped portion STP1 toward the center of the resting groove INS. Unlike the first stepped portion STP1, the second stepped portion STP2 may be formed in a partial region of the first stepped portion STP1. A shape of the second stepped portion STP2 may correspond to the shape of the upper notch portion PCT-DM (see FIG. 2A). An upper surface of the second stepped portion STP2 may extend from the upper surface of the first stepped portion STP1 without a space between the upper surfaces. That is, for example, the upper surface of the first stepped portion STP1 and the upper surface of the second stepped portion STP2 may both be parallel to a plane formed by a first direction DR1 and a second direction DR2. The first stepped portion STP1 and the second stepped portion STP2 may include a metal material or glass. The first stepped portion STP1 and the second stepped portion STP2 may not overlap the display module DM in a plan view and may overlap the transparent film EOF in a plan view.

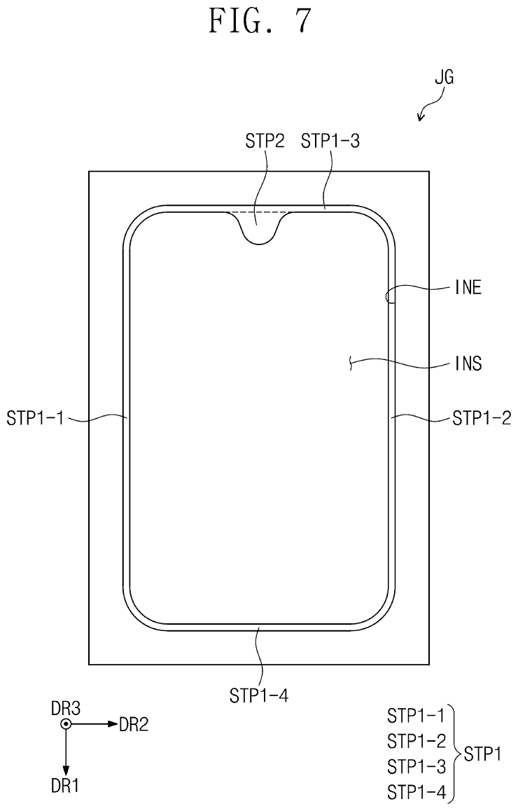

FIG. 7 is a plan view of a jig according to an embodiment supported by the present disclosure.

Referring to FIG. 7, a first stepped portion STP1 may include a (1-1)-th stepped portion STP1-1, a (1-2)-th stepped portion STP1-2, a (1-3)-th stepped portion STP1-3, and a (1-4)-th stepped portion STP1-4. The (1-1)-th stepped portion STP1-1 to the (1-4)-th stepped portion STP1-4 may be continuously connected to each other without being spaced apart from each other. A thickness of each of the (1-1)-th stepped portion STP1-1 to the (1-4)-th stepped portion STP1-4 may be constant. That is, for example, the (1-1)-th stepped portion STP1-1 to the (1-4)-th stepped portion STP1-4 may extend along an inner side surface INE while maintaining a constant distance from the inner side surface INE. A portion in which the (1-1)-th stepped portion STP1-1 to the (1-4)-th stepped portion STP1-4 are connected to each other may be curved.

An outer side surface of the first stepped portion STP1 and an outer side surface of a second stepped portion STP2 may form a closed curve in a plan view. A shape of the closed curve that the first stepped portion STP1 and the second stepped portion STP2 form may correspond to the shape of the display module DM (see FIG. 5B). Thus, the display module DM may be fixed in a resting groove INS through the outer side surface of the first stepped portion STP1 and the outer side surface of the second stepped portion STP2.

The (1-1)-th stepped portion STP1-1 may extend in a first direction DR1. The (1-2)-th stepped portion STP1-2 may extend in the first direction DR1 and face the (1-1)-th stepped portion STP1-1 in a second direction DR2. The (1-3)-th stepped portion STP1-3 may extend in the second direction DR2. The (1-4)-th stepped portion STP1-4 may extend in the second direction DR2 and face the (1-3)-th stepped portion STP1-3 in the first direction DR1.

The second stepped portion STP2 may protrude from the (1-3)-th stepped portion STP1-3 in the first direction DR1. The second stepped portion STP2 is illustrated as having a curved shape, but the shape of the second stepped portion STP2 is not limited thereto and may be changed to other various shapes supportive of features of the second stepped portion STP2.

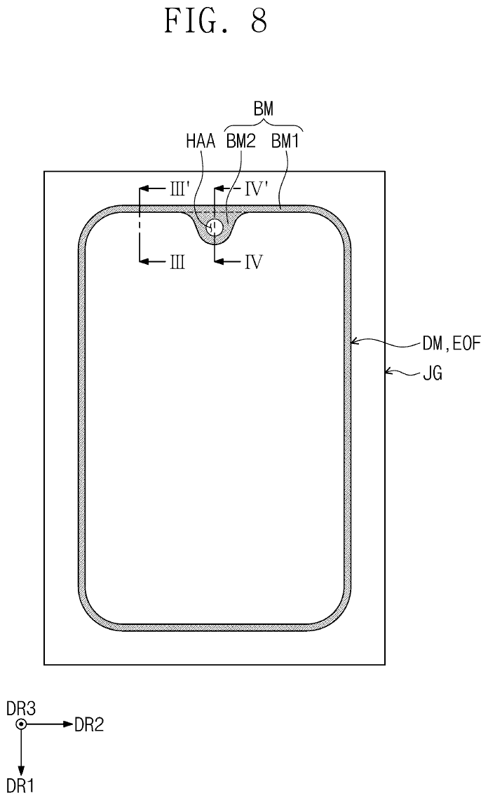

FIG. 8 is a plan view illustrating a display module and a transparent film rested on a jig according to an embodiment supported by the present disclosure.

Referring to FIGS. 7 and 8, an upper module in which a display module DM and a transparent film EOF are stacked may be rested on the jig JG described with reference to FIG. 7. The first stepped portion STP1 may overlap a first light blocking pattern BM1. The second stepped portion STP2 may overlap a second light blocking pattern BM2. The first stepped portion STP1 may not overlap a hole region HAA. A shape of the inner side surface INE of the jig JG may correspond to the shape of the transparent film EOF.

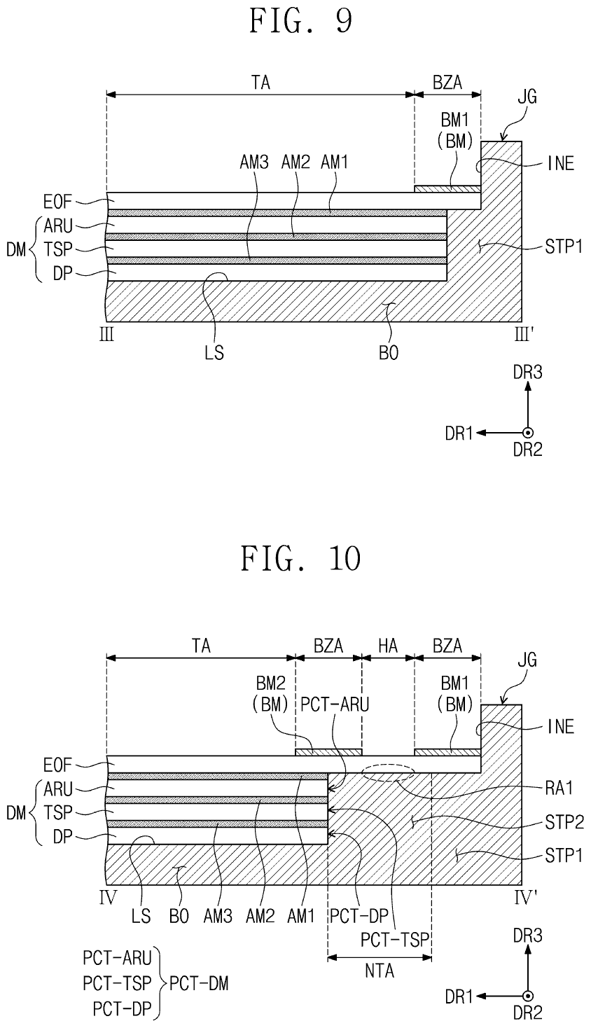

FIG. 9 is a cross-sectional view taken along line III-III′ in FIG. 8 according to an embodiment supported by the present disclosure.

Referring to FIG. 9, a lower surface of the display module DM may be rested on a lower surface of a stage BO. The outer side surface of the first stepped portion STP1 may be in contact with an outer side surface of the display module DM. However, the outer side surface of the first stepped portion STP1 and the outer side surface of the display module DM may be disposed such that the outer side surfaces are spaced apart from each other with a predetermined distance therebetween. A lower surface of an outer peripheral portion of the transparent film EOF may be rested on the first stepped portion STP1. The first stepped portion STP1 may be in contact with a lower surface of the transparent film EOF. The first stepped portion STP1 may prevent the outer peripheral portion of the transparent film EOF from sagging downward due to gravity. The first stepped portion STP1 may overlap the first light blocking pattern BM1. The first light blocking pattern BM1 may overlap the outer side surface of the display module DM.

An outer side surface of the transparent film EOF and an outer side surface of the first light blocking pattern BM1 may be aligned in a cross-sectional view. The inner side surface INE of the jig JG may be in contact with the outer side surface of the transparent film EOF and the outer side surface of the first light blocking pattern BM1. The outer side surface of the transparent film EOF may be disposed such that there is no space between the outer side surface of the transparent film EOF and the inner side surface INE of the jig JG. Accordingly, when a resin material is applied on the transparent film EOF, the resin material in a liquid state may be prevented from flowing into a lower component of the transparent film EOF.

The inner side surface INE of the jig JG may be release-coated using a release coating composition such as, for example, a silicone release agent. For example, embodiments of the present disclosure may include release-coating the inner side surface INE of the jig JG with the release coating composition. Accordingly, even if the resin material is applied on an upper surface of the transparent film EOF and cured, the release-coating may support easy removal of the jig JG.

FIG. 10 is a cross-sectional view taken along line IV-IV′ in FIG. 8 according to an embodiment supported by the present disclosure.

Referring to FIG. 10, a lower surface of the transparent film EOF may be in contact with an upper surface of the first stepped portion STP1 and an upper surface of the second stepped portion STP2. The outer side surface of the second stepped portion STP2 may be in contact with an upper notch portion PCT-DM of the display module DM. The second stepped portion STP2 may overlap a notch region NTA. A shape of the second stepped portion STP2 may correspond to the shape of the notch region NTA. The second stepped portion STP2 and the first stepped portion STP1 may have a continuous and integrated shape. The second stepped portion STP2 may extend in a first direction DR1 from the first stepped portion STP1. The second stepped portion STP2 may overlap the second light blocking pattern BM2. The second stepped portion STP2 may overlap the first light blocking pattern BM1. The first stepped portion STP1 may not overlap the second light blocking pattern BM2. The second stepped portion STP2 may overlap a hole region HA.

A height from a lower surface LS of a stage BO defining the resting groove INS to the first stepped portion STP1 and a height from the lower surface LS of the stage BO defining the resting groove INS to the second stepped portion may each be equal to a height of the display module DM. That is, for example, an upper surface of the display module DM, the upper surface of the first stepped portion STP1, and the upper surface of the second stepped portion STP2 may be parallel to a plane (e.g., one plane). In an example, the upper surface of the display module DM, the upper surface of the first stepped portion STP1, and the upper surface of the second stepped portion STP2 may be parallel to a plane formed by the first direction DR1 and a second direction DR2.

An average surface roughness of the upper surface of the second stepped portion STP2 may be about 50 nm or less. If the average surface roughness of the upper surface of the second stepped portion STP2 is more than about 50 nm, high roughness of the second stepped portion STP2 may be transferred to a coating window DW (see FIG. 12). That is, for example, roughness of an upper surface of the coating window DW (see FIG. 12) may increase. Particularly, an average surface roughness of a portion RA1 (hereinafter, a first upper surface portion) of the upper surface of the second stepped portion STP2 overlapping the hole region HA may be about 50 nm or less. For the same reason described with reference to the second stepped portion STP2, an average surface roughness of the upper surface of the first stepped portion STP1 may be about 50 nm or less.

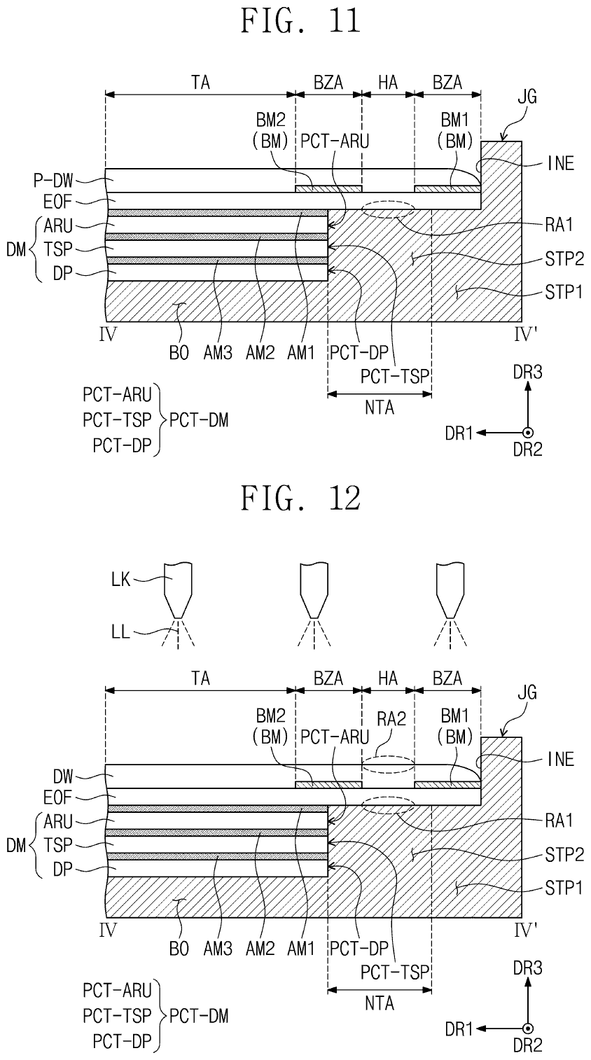

FIG. 11 is a cross-sectional view illustrating that a resin material is applied onto the transparent film in FIG. 10 according to an embodiment supported by the present disclosure. FIG. 12 is a cross-sectional view illustrating that the applied resin material in FIG. 11 according to an embodiment supported by the present disclosure is being cured.

Referring to FIGS. 11 and 12, a coating window DW may be formed on the transparent film EOF and a light blocking pattern BM. The coating window DW may be formed through applying a coating liquid onto the transparent film EOF and curing the applied coating liquid.

Referring to FIG. 11, coating liquid P-DW including a transparent resin material may be applied onto the transparent film EOF. The coating liquid P-DW may be an optically transparent insulating material. The coating liquid P-DW may be a resin material cured by being irradiated with laser. Due to viscosity of the coating liquid P-DW, the applied coating liquid P-DW may have a curved portion adjacent to the inner side INE of the jig JG.

Referring to FIGS. 11 and 12, laser LL generated from a separate exposure apparatus LK may be used to cure the coating liquid P-DW applied onto the transparent film EOF. As described herein, the formation of the coating window DW may support simplifying a manufacturing process, e.g., the manufacturing process may be implemented without a separate lamination process and a process of forming an optically clear adhesive (OCA) for attaching a window, thereby improving process reliability and reducing cost.

As described herein, if the coating window DW is formed through a process of applying and curing the coating liquid P-DW, surface roughness of each of the upper surface of the first stepped portion STP1 and the upper surface of the second stepped portion STP2 may be transferred to an upper surface of the coating window DW. If the surface roughness of each of the upper surface of the first stepped portion STP1 and the upper surface of the second stepped portion STP2 is high, the upper surface of the coating window DW may have high surface roughness. For example, if an average surface roughness of the first upper surface portion RA1 corresponding to the hole region HA increases, surface roughness of a second upper surface portion RA2 of the coating window DW corresponding to the first upper surface portion RA1 may increase. This may reduce surface quality of the coating window. Thus, an average surface roughness of each of the first stepped portion STP1 and the second stepped portion STP2 may be about 50 nm or less.

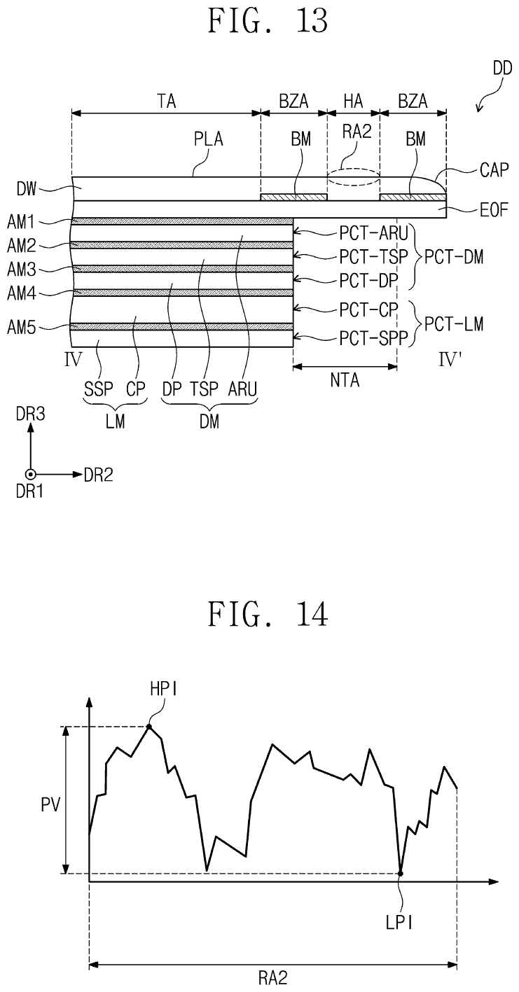

FIG. 13 is a cross-sectional view illustrating a lower module, a display module, a transparent film, and a coating window according to an embodiment supported by the present disclosure.

Referring to FIGS. 12 and 13, after forming the coating window DW, the jig JG may be removed. Since the inner side surface INE of the jig JG may be release-coated, the jig JG may be easily removed. Then, a display device DD may be formed by coupling a lower module LM to a display module DM.

FIG. 14 is a graph illustrating a height difference of an upper surface of a coating window according to an embodiment supported by the present disclosure. FIG. 14 is an enlarged view of a height difference in a third direction DR3 of a second upper surface portion RA2 (see FIG. 13) in FIG. 13.

Referring to FIGS. 13 and 14, surface roughness of the second upper surface portion RA2 is illustrated. The second upper surface portion RA2 of the coating window DW overlaps a hole region HA but does not overlap a light blocking pattern BM, and may thus be a portion to which surface roughness of the first upper surface portion RA1 (see FIG. 12) may be easily transferred. That is, for example, the second upper surface portion RA2 may be a portion of the coating window DW which has a highest probability of having high surface roughness.

A maximum height difference PV that is a height difference between a highest portion HPI (hereinafter, a high peak) of the second upper surface portion RA2 and a lowest portion LPI (hereinafter, a low peak) of the second upper surface portion RA2 may be about 0.95 μm or less. If the maximum height difference PV is more than about 0.95 μm, product quality of a display device DD may deteriorate, e.g., surface quality of the coating window DW may deteriorate, and visibility may reduce due to irregular refraction of light emitted from the display module DM on an upper surface of the coating window DW. According to one or more embodiments of the present disclosure, the maximum height difference PV of the second upper surface portion RA2 may be about 0.95 μm or less.

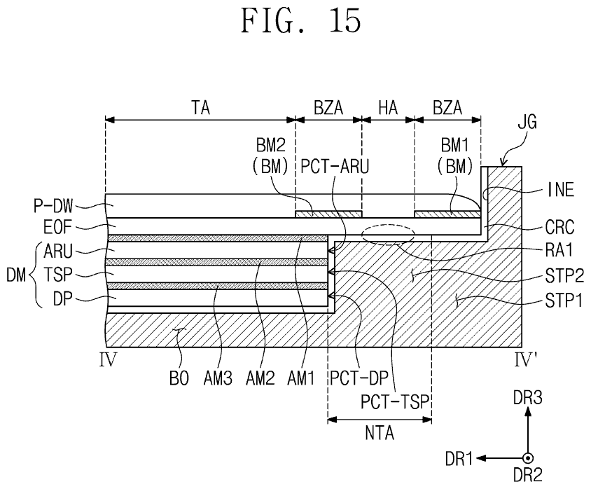

FIG. 15 is a cross-sectional view illustrating that a resin material is applied onto the transparent film in FIG. 10 according to an embodiment supported by the present disclosure.

Referring to FIG. 15, the jig JG may further include a cover layer CRC for covering the upper surface of the first stepped portion STP1 and the upper surface of the second stepped portion STP2. The cover layer CRC may prevent the average surface roughness of each of the first stepped portion STP1 and the second stepped portion STP2 from increasing due to corrosion or damage of the jig JG.

For example, if the jig JG includes a metal material, the upper surface of each of the first stepped portion STP1 and the second stepped portion STP2 may be mirror-finished to have an average surface roughness of about 50 nm or less. After mirror-finishing, the upper surface of each of the first stepped portion STP1 and the second stepped portion STP2 may be chrome-plated to form the cover layer CRC.

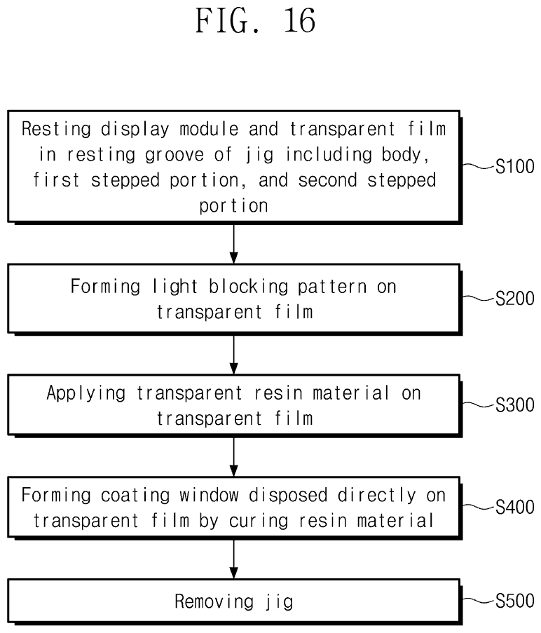

FIG. 16 is a flowchart illustrating operations of a display device manufacturing method according to an embodiment supported by the present disclosure.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 16, the display device manufacturing method may include resting a display module and a transparent film in a resting groove of a jig including a body, a first stepped portion, and a second stepped portion (S100), forming a light blocking pattern on the transparent film (S200), applying a transparent resin material onto the transparent film (S300), forming a coating window disposed directly on the transparent film by curing the resin material (S400), and removing the jig (S500).

Referring to FIGS. 6 and S100 of FIG. 16, the display module DM having defined therein the notch portion PCT-DM (see FIG. 5B), a side of which is recessed in a plan view, and the transparent film EOF disposed on the display module DM and covering the display module DM may be rested on the jig JG including the stage BO having the resting groove INS defined therein, the first stepped portion STP1, and the second stepped portion STP2.

Referring to FIGS. 9 and S200 of FIG. 16, the light blocking pattern BM may be formed on the transparent film EOF. The light blocking pattern BM may be formed by applying a light blocking material on an upper surface of the transparent film EOF and then curing the light blocking material using light generated from an exposure apparatus. However, the display device manufacturing method may omit the forming of the light blocking pattern BM (S200) if the transparent film EOF is rested on the jig JG in a state in which the light blocking pattern BM is included on the transparent film EOF.

Referring to FIGS. 11 and S300 of FIG. 16, the coating liquid P-DW including an optically transparent resin material may be applied onto the transparent film EOF.

Referring to FIGS. 12 and S400 of FIG. 16, by curing the resin material, the coating window DW disposed directly on the transparent film EOF and including a transparent resin material may be formed.

Referring to FIGS. 13 and S500 of FIG. 16, after forming the coating window DW, the jig JG may be removed.

A jig according to embodiments supported by the present disclosure may include a second stepped portion corresponding to a notch portion, which may prevent a portion of a transparent film corresponding to the notch portion from sagging downward.

An upper surface of a second stepped portion of a jig according to embodiments supported by the present disclosure may have an average surface roughness of about 50 nm or less, which may prevent surface unevenness of the second stepped portion from being transferred to a coating window.

A display device manufacturing method according to embodiments supported by the present disclosure may support the manufacturing of a coating window having a low surface roughness using a jig including a second stepped portion having a low average surface roughness.

Although descriptions have been made with reference to the example embodiments supported by the present disclosure described herein, it is understood that aspects of the present disclosure should not be limited to the example embodiments, but various changes and modifications may be made by one ordinary skilled in the art within the spirit and scope of aspects of the present disclosure as hereinafter claimed. Therefore, the technical scope supported by aspects of the present disclosure is not limited to the contents described in the detailed description of the specification, but should be defined by the accompanying claims.

What is claimed is:

1. A jig comprising:
a stage comprising a resting groove in which a display module and a transparent film are rested, wherein a side of a notch portion defined in the display module is recessed in a plan view, and the transparent film is disposed on the display module, covers the display module, and comprises an upper surface coated with a transparent resin material;
a first stepped portion protruding from an inner side surface of the stage defining the resting groove toward a center of the resting groove; and
a second stepped portion protruding from the first stepped portion toward the center of the resting groove,
wherein:
an upper surface of the first stepped portion and an upper surface of the second stepped portion are parallel to a plane, and
a shape of the second stepped portion corresponds to a shape of the notch portion.

2. The jig of claim 1, wherein an average surface roughness of the upper surface of the second stepped portion is about 50 nm or less.

3. The jig of claim 1, wherein the first stepped portion and the second stepped portion include a metal material or glass.

4. The jig of claim 1, wherein:
the first stepped portion and the second stepped portion include a metal material, and
the jig further comprises a cover layer covering the upper surface of the second stepped portion.

5. The jig of claim 1, wherein the first stepped portion and the second stepped portion are in contact with a lower surface of the transparent film.

6. The jig of claim 1, wherein an average surface roughness of the upper surface of the first stepped portion is about 50 nm or less.

7. The jig of claim 1, wherein the first stepped portion and the second stepped portion do not overlap the display module.

8. The jig of claim 1, wherein the inner side surface of the stage is in contact with an outer side surface of the transparent film.

9. The jig of claim 1, wherein:
an outer side surface of the first stepped portion and an outer side surface of the second stepped portion form a closed curve in a plan view, and
a shape of the closed curve corresponds to a shape of the display module.

10. The jig of claim 1, wherein a height from a lower surface of the stage defining the resting groove to the first stepped portion and a height from the lower surface of the stage defining the resting groove to the second stepped portion are each equal to a height of the display module.

11. The jig of claim 1, wherein:
a first light blocking pattern disposed along an outer side surface of the transparent film and a second light blocking pattern extending from the first light blocking pattern and overlapping the notch portion are disposed on the transparent film, and
the first stepped portion overlaps the first light blocking pattern.

12. The jig of claim 11, wherein the second stepped portion overlaps the second light blocking pattern.

13. The jig of claim 1, wherein the inner side surface of the stage is release-coated.

14. A display device manufacturing method comprising:
resting a display module and a transparent film on a jig, the jig comprising a first stepped portion, a second stepped portion, and a stage having a resting groove, wherein a side of a notch portion defined in the display module is recessed in a plan view, and the transparent film is disposed on the display module and covers the display module;
applying a transparent resin material onto the transparent film; and
forming a coating window disposed directly on the transparent film by curing a transparent resin material, wherein the coating window comprises the transparent resin material,
wherein a shape of the second stepped portion corresponds to a shape of the notch portion.

15. The display device manufacturing method of claim 14, wherein, in the resting of the display module and the transparent film on the jig, the transparent film is in contact with an upper surface of the first stepped portion and an upper surface of the second stepped portion.

16. The display device manufacturing method of claim 14, wherein:
the first stepped portion protrudes from an inner side surface of the stage defining the resting groove toward a center of the resting groove,
the second stepped portion protrudes from the first stepped portion toward the center of the resting groove, and
an upper surface of the first stepped portion and an upper surface of the second stepped portion are parallel to a plane.

17. The display device manufacturing method of claim 14, further comprising forming a light blocking pattern on the transparent film after resting the transparent film on the jig,
wherein the light blocking pattern includes a first light blocking pattern disposed along an outer side surface of the transparent film and a second light blocking pattern extending from the first light blocking pattern and corresponding to the notch portion.

18. The display device manufacturing method of claim 14, further comprising release-coating an inner side surface of the stage.

19. The display device manufacturing method of claim 14, wherein a maximum height difference between a highest portion of an upper surface of the coating window and a lowest portion of the upper surface is about 0.95 μm or less.

20. The display device manufacturing method of claim 14, wherein an average surface roughness of an upper surface of the second stepped portion is about 50 nm or less.
